(19) United States
(12) Patent Application Publication
(10) Pub. No.: US 2026/0018549 A1
(43) Pub. Date: Jan. 15, 2026

(54) Panel-Level Chip Packaging Structure and Method Based on Steel Plate Platform

(71) Applicant: Ningbo TRS Microelectronics Co., Ltd., Ningbo (CN)

(72) Inventor: Jianhua Zhang, Ningbo (CN)

(21) Appl. No.: 19/263,909

(22) Filed: Jul. 9, 2025

(30) Foreign Application Priority Data
Jul. 10, 2024 (CN) 2024109169381

(51) Int. Cl. H01L 23/00; H01L 21/683; H01L 23/13; H01L 23/14; H01L 23/31; H01L 23/498

(52) U.S. Cl. CPC H01L 24/13; H01L 21/6835; H01L 23/14; H01L 23/49811; H01L 24/16; H01L 24/96; H01L 24/97; H01L 23/13; H01L 23/3121; H01L 24/14; H01L 2224/13013; H01L 2224/13016; H01L 2224/13147; H01L 2224/14131; H01L 2224/16245; H01L 2924/38

(57) ABSTRACT

The present disclosure relates to the field of semiconductor packaging technologies, and in particular, to a panel-level chip packaging structure and method based on a steel plate platform. The packaging structure includes: a steel plate; a gold-nickel layer plated on the steel plate, where the gold-nickel layer is provided with upwardly protruding pins corresponding to a chip; the chip flipped to the corresponding pins; and a molded body coating the corresponding chip and the gold-nickel layer. According to the packaging structure and method of the present disclosure, an overall thickness of a chip-packaged product can be reduced. A wire bonding process and an electroplating process are further omitted, so that the overall thickness of chip packaging can be further reduced. An ultra-thin packaging structure can be implemented, the chip packaging efficiency can further be improved, and a complete-process chip packaging cycle can be shortened.

### TECHNICAL FIELD

The present disclosure relates to the field of semiconductor packaging technologies, and in particular, to a panel-level chip packaging structure and method based on a steel plate platform.

### BACKGROUND

A conventional chip packaging structure is shown in FIG. 1. The chip packaging structure includes a substrate 11, a frame 12 disposed on the substrate 11, a chip 13 disposed on a base island 122 formed in the frame 12, and a pin 121 disposed on an inner side of the frame 12. The pin 121 is connected to the chip 12 by forming a welding wire 14 through a wire bonding process. A thickness of the frame 12 is at least approximately 0.2 mm, and the welding wire 14 needs to have an arc bent upwardly to ensure stability. Consequently, such a packaging structure has problems of small space for improving thickness, high cost caused by consumption of the frame, low utilization of the frame, and the like.

### SUMMARY

An objective of the present disclosure is to overcome the defects of the related art, and provide a panel-level chip packaging structure and method based on a steel plate platform, to resolve problems of small space for improving thickness, high cost caused by consumption of a frame, low utilization of the frame, and the like in a conventional chip packaging structure.

To achieve the foregoing objective, the following technical solutions are adopted.

The present disclosure provides a panel-level chip packaging structure based on a steel plate platform, including:
a steel plate;
a gold-nickel layer plated on the steel plate, where the gold-nickel layer is provided with upwardly protruding pins corresponding to a chip;
the chip flipped to the corresponding pins; and
a molded body coating the corresponding chip and the gold-nickel layer.

The panel-level chip packaging structure based on a steel plate platform of the present disclosure is further improved in that the steel plate is removable after the molded body is formed.

The panel-level chip packaging structure based on a steel plate platform of the present disclosure is further improved in that the gold-nickel layer includes a gold layer plated on the steel plate and a nickel layer plated on the gold layer. The gold layer and the nickel layer are of the same shape.

The panel-level chip packaging structure based on a steel plate platform of the present disclosure is further improved in that a plurality of pins corresponding to the chip on the gold-nickel layer are arranged in an array and the pins are disposed within a coverage region of the corresponding chip.

The panel-level chip packaging structure based on a steel plate platform of the present disclosure is further improved in that a plurality of such chips are provided.

The panel-level chip packaging structure based on a steel plate platform of the present disclosure is further improved in that the steel plate has a thickness of 0.1 mm to 0.2 mm.

The panel-level chip packaging structure based on a steel plate platform of the present disclosure is further improved in that the gold-nickel layer has a thickness of 0.06 mm to 0.065 mm.

The panel-level chip packaging structure based on a steel plate platform of the present disclosure is further improved in that protrusions are disposed at a bottom of the chip and the protrusions are connected to the corresponding pins.

The present disclosure further provides a panel-level chip packaging method based on a steel plate platform, including the following steps:
providing a steel plate;
plating a gold-nickel layer on the steel plate, where the gold-nickel layer is provided with upwardly protruding pins corresponding to a chip;
mounting the chip to the corresponding pins by using a flipping process; and
molding the chip and the corresponding gold-nickel layer to form a molded body coating the corresponding chip and the gold-nickel layer, thereby completing packaging of the chip.

The panel-level chip packaging method based on a steel plate platform of the present disclosure is further improved in that the steel plate is removed after the molded body is formed.

The molded body is cut by using a resin knife having a thickness of 0.08 mm to obtain a packaged product.

The panel-level chip packaging structure and method based on a steel plate platform of the present disclosure have the following beneficial effects.

In the present disclosure, a steel plate is used as a platform, and a gold-nickel layer is placed on the steel plate. The plated gold-nickel layer is used as a frame o chip packaging, and pins are disposed corresponding to the chip. The chip is connected to the pins by using a flipping process. A thickness of the gold-nickel layer is less than that of a conventional packaging frame, thereby reducing an overall thickness of a chip-packaged product. The chip is processed by using the flipping process, and a wire bonding process and an electroplating process are further omitted, so that the overall thickness of chip packaging can be further reduced. An ultra-thin packaging structure can be implemented, the chip packaging efficiency can further be improved, and a complete-process chip packaging cycle can be shortened.

In the present disclosure, the gold-nickel layer is used as a frame structure, thereby eliminating frame bars disposed horizontally and longitudinally in the frame structure in the related art. The gold-nickel layer only needs to include corresponding pins on the steel plate according to the quantity of required pins for the chip, so that frame utilization can be improved, and frame material costs can be reduced.

In the present disclosure, the gold-nickel layer is used to form the pins to be connected to the chip, a terminal after chip packaging is an exposed portion of the gold layer, and the gold layer is used as an exposed terminal, so that the packaging structure of the chip has high reliability.

In the present disclosure, the chip is connected to the pins by using a flipping process, and the pins are formed by the gold-nickel layer. A tinning process can be omitted, thereby avoiding problems of formation of tin whiskers, plating shedding, low reliability, susceptibility to corrosion by acid and alkali, a limited use environment, and the like.

According to the packaging structure and method of the present disclosure, the steel plate may be removed before cutting, so that the molded body can be cut by using a resin knife having a thickness of 0.08 mm. A cutting gap is only 0.08 mm, so that a distance between adjacent chips can be shortened, the quantity of chips distributed on the steel plate can be increased, and packaging efficiency of a packaged product can be improved. A cutting gap of the conventional frame structure is approximately 0.32 mm. To cut a copper frame structure, a cutting knife having a thickness of at least 0.32 mm is needed.

### BRIEF DESCRIPTION OF THE DRAWINGS

FIG. 1 is a schematic diagram of a chip packaging structure in the related art.

FIG. 2 is a schematic structural diagram of a single packaged product of a panel-level chip packaging structure based on a steel plate platform according to the present disclosure.

FIG. 3 is a schematic structural diagram of two adjacent cut packaged products of a panel-level chip packaging structure based on a steel plate platform according to the present disclosure.

FIG. 4 is a schematic structural diagram of pins disposed on a steel plate in a panel-level chip packaging structure based on a steel plate platform according to the present disclosure.

FIG. 5 is a top view of a package formed on a steel plate in a panel-level chip packaging structure based on a steel plate platform according to the present disclosure.

FIG. 6 is a flowchart of a panel-level chip packaging method based on a steel plate platform according to the present disclosure.

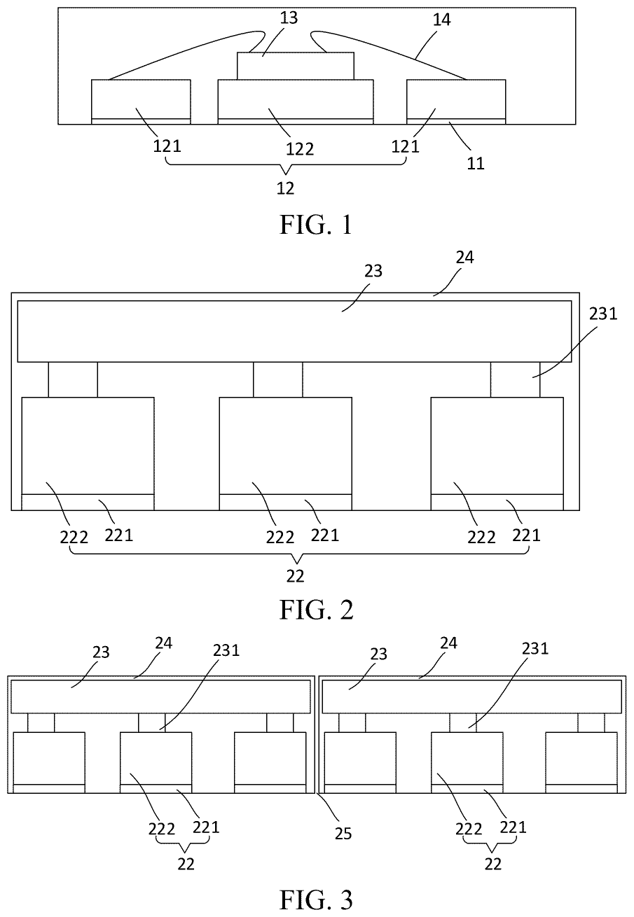

### DETAILED DESCRIPTION

The present disclosure will be further described below with reference to the accompanying drawings and specific embodiments.

Referring to FIG. 2, the present disclosure provides a panel-level chip packaging structure and method based on a steel plate platform, which are intended to implement an ultra-thin high-density packaging structure and are mainly applied to the field of semiconductor chip packaging, to resolve problems of small space for improving thickness and susceptibility to substrate leakage in a conventional packaging structure, problems of ball detachment, cratering, wire damage, wire sweep, and low efficiency of a wire bonding process in the conventional packaging structure, problems of formation of tin whiskers, plating shedding, low reliability, susceptibility to corrosion by acid and alkali, and a limited use environment in pin surface tinning, and problems of high cost and low frame utilization due to consumption of a main material frame in the conventional packaging structure. According to the packaging structure and method of the present disclosure, a gold-nickel layer is plated on a thin steel plate to serve as a chip packaging frame. A structure form of the gold-nickel layer is designed according to the quantity of pins required for a chip. The chip is connected to the pins formed by the gold-nickel layer by using a flipping process, thereby achieving high density and high reliability, improving frame utilization, reducing frame material costs, omitting a wire bonding process and an electroplating process, improving chip packaging efficiency, and shortening a complete-process chip packaging cycle. A panel-level chip packaging structure and method based on a steel plate platform of the present disclosure are described below with reference to the accompanying drawings.

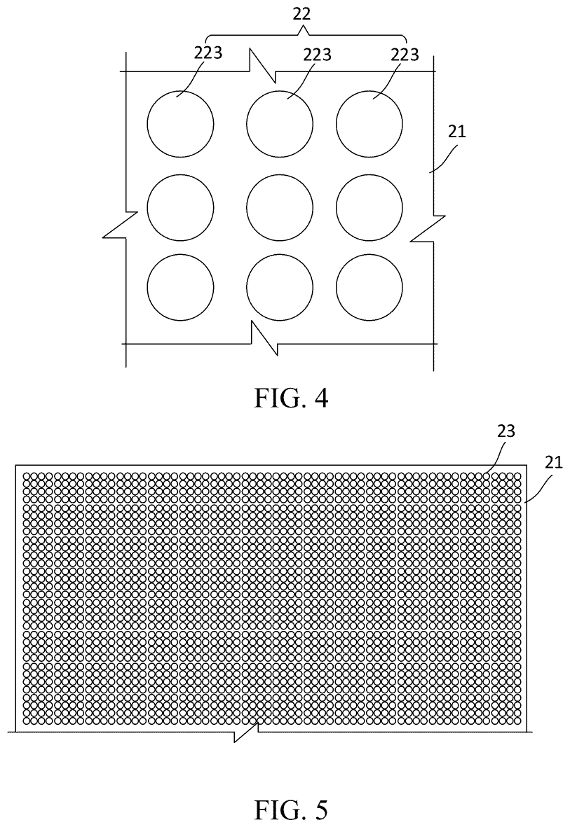

FIG. 2 shows a schematic structural diagram of a single packaged product of a panel-level chip packaging structure based on a steel plate platform according to the present disclosure. FIG. 4 shows a schematic structural diagram of pins disposed on a steel plate in a panel-level chip packaging structure based on a steel plate platform according to the present disclosure. FIG. 5 shows a top view of a package formed on a steel plate in a panel-level chip packaging structure based on a steel plate platform according to the present disclosure. With reference to FIG. 2, FIG. 4, and FIG. 5, the following describes a panel-level chip packaging structure based on a steel plate platform according to the present disclosure.

As shown in FIG. 2, FIG. 4, and FIG. 5, the panel-level chip packaging structure based on a steel plate platform of the present disclosure includes a steel plate 21, a gold-nickel layer 22, a chip 23, and a molded body 24. The gold-nickel layer 22 is plated on a steel plate 21. The gold-nickel layer 22 is provided with upwardly protruding pins 223 corresponding to the chip 23. The chip 23 is flipped to the corresponding pins 223. The molded body 24 coats the corresponding chip 23 and the gold-nickel layer 22. The molded body 24 is preferably formed by a molding compound.

In the present disclosure, the gold-nickel layer 22 is used to form the pins 223 to be connected to the chip 23. The gold-nickel layer 22 replaces a frame in a conventional packaging structure. The gold-nickel layer 22 is formed by a plurality of pins 223 disposed on the steel plate 21. The pins 223 protrude upwardly from an upper surface of the steel plate 21. In this way, in the present disclosure, compared with the frame of the conventional packaging structure, the present disclosure can greatly improve the material utilization of the gold-nickel layer 22 and reduce material costs by using the gold-nickel layer 22 to form the pins 223 to be connected to the chip 23. Further, the pins 223 formed by the gold-nickel layer 22 replace frame copper in the related art, so as to omit a tinning process. Correspondingly, problems caused by the tinning process such as formation of tin whiskers, plating shedding, low reliability, susceptibility to corrosion by acid and alkali, and a limited use environment can be avoided.

In a specific implementation of the present disclosure, the steel plate 21 in the packaging structure of the present disclosure may be removed after the molded body 24 is formed.

Specifically, after the gold-nickel layer 22 is plated on the steel plate 21, the chip 23 is connected to the gold-nickel layer 22, and then a molding compound is injected onto the steel plate 21. The molding compound may be an adhesive for packaging. The molding compound coats the chip 23 and the corresponding gold-nickel layer 22. The molded body 24 is formed after the molding compound is formed. To be specific, the steel plate 21 may be torn from the molded body 24 manually or the steel plate may be separated by using a robot. After the molded body 24 is separated from the steel plate 21, the entire molded body 24 has a plate shape, and coats a plurality of chips 23 therein. Then, the molded body 24 is cut to obtain packaged products. The structure of the obtained packaged product is shown in FIG. 2. A bottom surface of the gold-nickel layer 22 is exposed on a bottom surface of the molded body 24 to form an external terminal of the chip 23.

The molded body 24 is cut by using a resin knife having a thickness of 0.08 mm. The cutting speed is high, and the cutting knife cannot be damaged or the like. Because the molded body 24 has an adhesive structure with hardness significantly lower than metal, an ultra-thin blade may be used for cutting. As shown in FIG. 3, a cutting gap 25 between two adjacent chips 23 has a thickness of 0.08 mm. In this way, the chips are arranged more tightly with small spacing when regions of the chips are designed on the steel plate 21, to implement high-density packaging. However, in the conventional packaging structure, a cutting knife having a thickness of at least 0.32 mm is selected to cut a copper frame. In this way, a chip spacing in the conventional packaging structure is 4 times that of a chip spacing in the present disclosure. When a steel plate having a size consistent with that of the frame in the conventional packaging structure is used, the present disclosure can improve a chip setting density, improve the quantity of single-packaged chips, and further improve chip production efficiency.

Further, the steel plate 21 of the present disclosure has a thickness of 0.1 mm to 0.2 mm, inclusive. The thickness of the steel plate 21 is preferably 0.15 mm. Since the steel plate has a small thickness, the steel plate may be removed after the molded body 24 is formed.

In a specific implementation of the present disclosure, as shown in FIG. 2 to FIG. 4, the gold-nickel layer 22 includes a gold layer 221 plated on the steel plate 21 and a nickel layer 222 plated on the gold layer 221. The gold layer 221 and the nickel layer 222 are of the same shape.

The gold layer 221 is first plated on the steel plate 21, and then the nickel layer 222 is plated on the gold layer 221, so that after the chip 23 is molded, a bottom surface of the gold layer 221 can be exposed to form a terminal. The gold layer 221 is used as the terminal to replace a conventional copper terminal, thereby improving reliability of the chip and omitting a tinning process.

Further, the gold-nickel layer 22 has a thickness of 0.06 mm to 0.065 mm. Preferably, an entire thickness of the gold-nickel layer 22 is 0.06 mm. Compared with a copper frame thickness of 0.2 mm in the related art, the entire thickness of the chip 23 after packaging can be greatly reduced, thereby implementing ultra-thin packaging.

Still further, a thickness of the nickel layer 222 is 10 times to 12 times that of the gold layer 221, to reduce material costs.

Still further, as shown in FIG. 4, a plurality of pins 223 correspond to the chip 23 on the gold-nickel layer 22, and the plurality of pins 223 are arranged in an array. With reference to FIG. 2, the pins 223 are disposed within a coverage region of the corresponding chip 23.

The pins 223 are disposed in an array in a rectangular region. To be specific, the pins are arranged in a horizontal direction and a longitudinal direction. This arrangement manner enables more pins 223 to be arranged. The quantity may be selected according to the quantity of terminals that need to be led out from the chip 23. Layout positions or regions of the pins 223 correspond to a disposition region of the chip 23. To be specific, the pins 223 do not extend beyond a disposition range of the chip 23. In this way, the size of a single packaged product cut after packaging is similar to the size of the chip 23, and only a layer of molding compound coating the chip 23 is added. The size of the packaged product of the present disclosure is miniaturized to the greatest extent, so that the size of the packaged product can be equivalent to the size of the chip.

Preferably, the pin 223 is columnar, and may be cylindrical, square columnar, prismatic, or the like. The pins 223 have flat top surfaces for connection to the chip 23.

In a specific implementation of the present disclosure, as shown in FIG. 2 to FIG. 5, protrusions 231 are disposed at a bottom of the chip 23. The protrusions 231 are connected to the corresponding pins 223.

The protrusions 231 protrude downwardly from the bottom surface of the chip 23. The positions and quantity of the pins 223 are designed according to the disposition positions and quantity of the protrusions 231 on the chip 23. A cross-sectional size of the pins 223 is greater than a cross-sectional size of the protrusions 231, so that the protrusions 231 are securely connected to the corresponding pins 223. The protrusion 231 and the pin 223 may be welded. For example, the protrusion 231 and the pin 223 are welded by using a tin paste.

Preferably, the protrusions 231 are columnar or spherical.

Further, a rewiring layer is disposed within the chip 23, and a circuit inside the chip 23 is connected to the protrusions 231 disposed at the bottom by using the rewiring layer.

Still further, the protrusion 231 includes an alloy protrusion portion connected to the chip 23 and a copper protrusion portion connected to the alloy protrusion portion. The copper protrusion portion is configured to be connected to the pin 223. The alloy protrusion portion is preferably selected from an alloy formed by a mixture of tin and silver. The content of silver in the alloy protrusion portion is 1.5% to 2%, inclusive. A melting temperature of the alloy protrusion portion is high, and the chip 23 can be well supported, so that supporting strength can be improved. Preferably, the copper protrusion portion has a columnar shape, the alloy protrusion portion has a semi-spherical shape, an arc surface of the alloy protrusion portion is connected to the bottom of the chip 23.

Still further, a height of the alloy protrusion portion is half of a height of the copper protrusion portion.

Still further, a plurality of such chips 23 on the steel plate 21 are provided, and design regions of the chips 23 on the steel plate 21 may be equally spaced apart in a horizontal direction and a longitudinal direction.

In the present disclosure, panel-level packaging is formed by using the steel plate 21. Compared with conventional frame strip packaging, 14 conventional frame strips can be disposed on the steel plate 21 of the present disclosure. Compared with the conventional packaging structure, the present disclosure can greatly improve packaging efficiency.

In the present disclosure, the chip is flipped onto the pins by using the protrusions formed at the bottom. Compared with a manner of packaging by using a welding wire in the conventional packaging structure, the thickness of the chip after packaging can be further reduced, thereby implementing ultra-thin packaging.

The present disclosure further provides a panel-level chip packaging method based on a steel plate platform. The packaging method is described below.

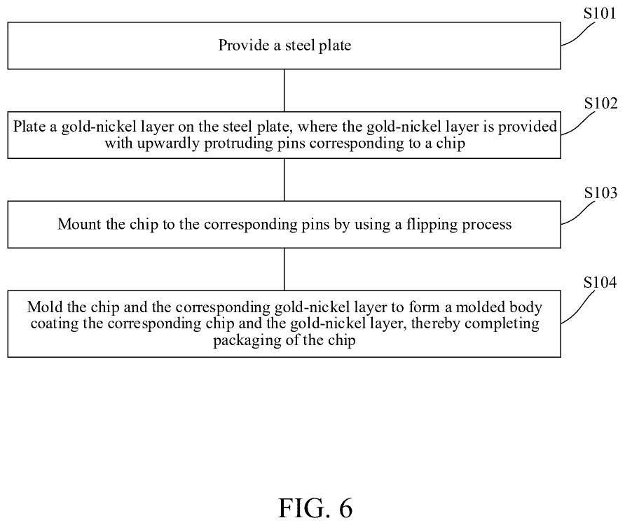

As shown in FIG. 6, the packaging method of the present disclosure includes the following steps:

Step S101: Provide a steel plate. Next, step S102 is performed.

Step S102: Plate a gold-nickel layer on the steel plate, where the gold-nickel layer is provided with upwardly protruding pins corresponding to a chip. Next, step S103 is performed.

Step S103: Mount the chip to the corresponding pins by using a flipping process. Next, step S104 is performed.

Step S104: Mold the chip and the corresponding gold-nickel layer to form a molded body coating the corresponding chip and the gold-nickel layer, thereby completing packaging of the chip.

In a specific implementation of the present disclosure, the steel plate is removed after the molded body is formed.

The molded body is cut by using a resin knife having a thickness of 0.08 mm to obtain a packaged product.

In a specific implementation of the present disclosure, as shown in FIG. 2 to FIG. 5, the provided steel plate 21 has a thickness of 0.015 mm. The pins are made within the corresponding layout regions on an upper surface of the steel plate 21 according to a layout region of the chip 23 and the quantity and positions of the pins required for the chip 23. A gold layer 221 is first plated on the steel plate 21. The gold layers 221 correspond to the designed pins in position and quantity. The gold layer 221 has a small thickness such as a thickness of 0.005 mm. Then, a nickel layer 222 is plated on the gold layer 221. A thickness of the nickel layer 222 is 10 times to 12 times that of the gold layer 221. For example, the thickness of the nickel layer 222 may be 0.06 mm or 0.055 mm. The gold layer 222 and the nickel layer 221 are of the same shape. A plurality of pins 223 formed by the gold layer 221 and the nickel layer 222 are plated on the steel plate 21. These pins 223 form the gold-nickel layer 23, which is equivalent to a frame for chip packaging. Supported by the steel plate 21, the pins 223 may be arranged in an array in the chip layout region. The pins 223 do not need to be connected to each other, so that the material utilization of the gold-nickel layer 23 reaches 100%.

In a specific implementation of the present disclosure, the chip 23 is mounted by using a flipping process. A rewiring layer is disposed within the chip 23. A circuit wire within the chip 23 is led to the bottom of the chip 23 by using the rewiring layer. Protrusions 231 connected to the rewiring layer are formed at the bottom of the chip 23. The protrusions 231 support the chip 23 on one hand, and are connected to the pins on the other hand. A part of the protrusions 231 are tin-silver alloys and a part of the protrusions are copper, so that supporting strength can be improved, and chip mounting stability can be ensured.

In a specific implementation of the present disclosure, after the chip is mounted, a molding compound is injected onto the steel plate. The chips and the gold-nickel layer are coated with the molding compound, and the molded body 24 is formed after the molding compound is formed. The entire molded body 24 has a plate shape. After the molded body 24 is formed, the molded body 24 is separated from the steel plate 21, and then the molded body 24 is placed on a mold. A side portion of the mold corresponding to the chip is provided with a cutting groove. The molded body 24 is cut along the cutting groove in the mold by using a resin knife having a thickness of 0.08 mm, thereby obtaining a plurality of packaged products. Because the steel plate may be removed before cutting, the chip may be cut by using an ultra-thin cutting knife. In this way, when chip layout regions are disposed on the steel plate, a spacing between the layout regions can be reduced, so that the quantity of the layout regions namely the chips arranged can be improved, thereby improving the chip packaging efficiency.

The present disclosure is described in detail above with reference to the accompanying drawings. A person of ordinary skill in the art may make various variations to the present disclosure according to the foregoing description. Therefore, some details in the embodiments should not be construed as a limitation to the present disclosure. The scope of protection of the present disclosure is defined by the appended claims.

What is claimed is:

1. A panel-level chip packaging structure based on a steel plate platform, comprising:
a steel plate;
a gold-nickel layer plated on the steel plate, the gold-nickel layer being provided with upwardly protruding pins corresponding to a chip;
the chip flipped to the corresponding pins; and
a molded body coating the corresponding chip and the gold-nickel layer, wherein the steel plate is removable after the molded body is formed;
the gold-nickel layer comprises a gold layer plated on the steel plate and a nickel layer plated on the gold layer, the gold layer and the nickel layer are of the same shape, and the gold layers correspond to the designed pins in position and quantity;
a plurality of pins corresponding to the chip on the gold-nickel layer are arranged in an array, and the pins are disposed within a coverage region of the corresponding chip;
a plurality of such chips are provided, design regions of the chips on the steel plate are equally spaced apart in a horizontal direction and a longitudinal direction, and the pins have flat top surfaces for connection to the chip;
the steel plate has a thickness of 0.1 mm to 0.2 mm;
the gold-nickel layer has a thickness of 0.06 mm to 0.065 mm;
protrusions are disposed at a bottom of the chip, and the protrusions are connected to the corresponding pins;
the molded body is cut to obtain a packaged product, the molded body is specifically cut by using a resin knife having a thickness of 0.08 mm during cutting of the molded body, and the chips are arranged more tightly with small spacing when regions of the chips are designed on the steel plate, to implement high-density packaging;
a thickness of the nickel layer is 10 times to 12 times that of the gold layer;
layout positions or regions of the pins correspond to a disposition region of the chip;
the protrusion disposed at the bottom of the chip comprises an alloy protrusion portion connected to the chip and a copper protrusion portion connected to the alloy protrusion portion, the copper protrusion portion is configured to be connected to the pin, the alloy protrusion portion is selected from an alloy formed by a mixture of tin and 1.5% to 2% of silver, the copper protrusion portion has a columnar shape, the alloy protrusion portion has a semi-spherical shape, an arc surface of the alloy protrusion portion is connected to the bottom of the chip, and the positions and quantity of the pins are designed according to the disposition positions and quantity of the protrusions on the chip; and
a height of the alloy protrusion portion is half of a height of the copper protrusion portion.

2. A panel-level chip packaging method based on a steel plate platform, comprising the following steps:
providing a steel plate;
plating a gold-nickel layer on the steel plate, the gold-nickel layer being provided with upwardly protruding pins corresponding to a chip;
mounting the chip to the corresponding pins by using a flipping process, wherein a plurality of such chips are provided, design regions of the chips on the steel plate are equally spaced apart in a horizontal direction and a longitudinal direction, and the pins have flat top surfaces for connection to the chip;
molding the chip and the corresponding gold-nickel layer to form a molded body coating the corresponding chip and the gold-nickel layer, thereby completing packaging of the chip;
removing the steel plate after the molded body is formed;
cutting the molded body by using a resin knife having a thickness of 0.08 mm to obtain a packaged product, wherein
the provided steel plate has a thickness of 0.015 mm, the pins are made within the corresponding layout regions on an upper surface of the steel plate according to a layout region of the chip and the quantity and positions of the pins required for the chip, a gold layer is first plated on the steel plate, the gold layers correspond to the designed pins in position and quantity, a nickel layer is plated on the gold layer, a thickness of the nickel layer is 10 times to 12 times that of the gold layer, the gold layer and the nickel layer are of the same shape, and the gold-nickel layer has a thickness of 0.06 mm to 0.065 mm; and
cutting the molded body by using a resin knife having a thickness of 0.08 mm during cutting of the molded body, wherein the chips are arranged more tightly with small spacing when regions of the chips are designed on the steel plate, to implement high-density packaging;
the protrusion disposed at the bottom of the chip comprises an alloy protrusion portion connected to the chip and a copper protrusion portion connected to the alloy protrusion portion, the copper protrusion portion is configured to be connected to the pin, the alloy protrusion portion is selected from an alloy formed by a mixture of tin and 1.5% to 2% of silver, the copper protrusion portion has a columnar shape, the alloy protrusion portion has a semi-spherical shape, an arc surface of the alloy protrusion portion is connected to the bottom of the chip, and the positions and quantity of the pins are designed according to the disposition positions and quantity of the protrusions on the chip; and
a height of the alloy protrusion portion is half of a height of the copper protrusion portion.
